(19) United States
(12) Patent Application Publication
(10) Pub. No.: US 2013/0026690 A1
(43) Pub. Date: Jan. 31, 2013

(54) WET-ETCHING JIG

(71) Applicant: Yoichiro Nishimoto, Chiyoda-ku (JP)

(72) Inventor: Yoichiro Nishimoto, Chiyoda-ku (JP)

(73) Assignee: Mitsubishi Electric Corporation, Tokyo (JP)

(21) Appl. No.: 13/640,407

(22) PCT Filed: Apr. 26, 2010
(86) PCT No.: PCT/JP2010/057384

§ 371 Date: Oct. 10, 2012

(51) Int. Cl. H01L 21/683

(52) U.S. Cl. 269/21

(57) ABSTRACT

A wet-etching jig, which is a wet-etching jig that holds a plate workpiece when the workpiece is wet-etched, includes: a holding unit configured to include a suction unit in which a suction port is formed for absorbing the air and a first close contact unit that is provided to surround the suction unit and that can closely contact a first surface of the workpiece to surround a predetermined region of the first surface; an exhaust path that communicates with the suction port; and a check valve that is provided in the exhaust path to intercept a flow of the air in a direction toward the suction unit and to permit a flow of the air from the suction unit.

### FIELD

The present invention relates to a wet-etching jig and particularly relates to a wet-etching jig for sucking and holding a plate workpiece.

### BACKGROUND

The power cost of solar energy generation is still high, and it is required to improve conversion efficiency while reducing the material cost and manufacturing cost for solar cells. To meet the demand, thinning of wafers that account for a high proportion of the material cost is performed. The wafer thinning leads to reduction in a light absorption layer and increase in relative importance of a front surface of each wafer. Accordingly, to manufacture solar cells having high conversion efficiency, a light confinement technique and a passivation (inactivation) technique for front and back surfaces of the solar cells become more important.

In most of currently available crystalline silicon solar cells, minute irregularities called texture (hereinafter, “Tex.”) are provided on a light-receiving surface of each of the solar cells to reduce reflectance of the front surface, high-concentration diffusion layers having the same conduction type as that of a wafer to be used are provided on the back surface of the solar cell, and the back surface is passivated with the internal electric field of a junction therebetween. The diffusion layers on the back surface are referred to as “BSF (Back Surface Field) layers”. Generally, each of the BSF layers is formed by using a p-wafer and printing and firing Al paste on the back surface (hereinafter, this BSF is referred to as “Al-BSF”).

However, it is known that the wafer thinning is less compatible with the Al-BSF, and the Al-BSF causes disturbance of the wafer thinning. More specifically, because of a difference in coefficients of thermal expansion between Al and Si, an internal stress is applied to the fired wafer. Accordingly, warpage of cells is more conspicuous when the wafer is thinner, which adversely influences later module manufacturing steps. In these circumstances, therefore, a technique that enables to passivate the back surface with an insulating film is being studied as a technique that replaces the Al-BSF technique.

It is known that the presence of Tex. on the back surface of the solar cell of such a type as to passivate the back surface thereof with an insulating film causes degradation in back-surface passivation characteristics. Therefore, it is desirable that there is no Tex. on the back surface.

To form the Tex., wet etching is often used because the wet etching is suited for mass production. In the wet etching, it is necessary to perform etching on each wafer in a state of masking one of surfaces of the wafer with resist or the like to form Tex. only on the front surface of the wafer and to prevent formation of the Tex. on the back surface thereof. However, the formation and removal of the resist disadvantageously increases the manufacturing cost.

To solve this problem, techniques that enable to etch only one surface of a plate workpiece by dipping the workpiece into a chemical solution in a state of absorbing the workpiece are disclosed in Patent Literatures 1 and 2, for example.

### CITATION LIST

### Patent Literatures

Patent Literature 1: Japanese Patent Application Laid-open No. H03-102728

Patent Literature 2: Japanese Patent Application Laid-open No. H09-246235

### SUMMARY

### Technical Problem

However, the disclosed techniques have the following problems. It is difficult to meet the demand of mass production of solar cells because workpieces, vacuum pumps, tubes, and the like are provided substantially in one-to-one correspondence. For example, when 100 or more workpieces are collectively processed, it is necessary to prepare as many vacuum pumps and the like as the workpieces, which is quite impractical.

The present invention has been achieved to solve the above problems, and an object of the present invention is to provide a wet-etching jig that can meet the demand of mass production of solar cells and that can suppress its manufacturing cost.

### Solution to Problem

There is provided a wet-etching jig according to an aspect of the present invention that holds a plate workpiece when the workpiece is wet-etched, the wet-etching jig including: a holding unit that includes a suction unit in which a suction port is formed for absorbing air, and a first close contact unit that is provided to surround the suction unit and that can closely contact a first surface of the workpiece to surround a predetermined region of the first surface; an exhaust path that communicates with the suction port; and a check valve that is provided in the exhaust path to intercept a flow of the air in a direction toward the suction unit and to permit a flow of the air from the suction unit.

### Advantageous Effects of Invention

The wet-etching jig according to the present invention can meet the demand of mass production of solar cells and suppress its manufacturing cost.

### BRIEF DESCRIPTION OF DRAWINGS

FIG. 1 is a front view of an external appearance of a wet-etching jig according to a first embodiment of the present invention.

FIG. 2 is a side view of the wet-etching jig shown in FIG. 1.

FIG. 3 is a cross-sectional view taken along a line A-A in a direction of arrows shown in FIG. 1.

FIG. 4 depicts a state where the wet-etching jig holds wafers.

FIG. 5 is a cross-sectional view of the wet-etching jig that holds the wafers. FIG. 6 is a front view of the wet-etching jig that holds the wafers.

FIG. 7 is a plan view of a state of housing the wet-etching jigs in a cassette.

FIG. 8 is a cross-sectional view taken along a line B-B in a direction of arrows shown in FIG. 7.

FIG. 9 is a view taken along a line C-C in a direction of arrows shown in FIG. 7.

FIG. 10 depicts a state of detaching the wafers from the wet-etching jig.

### DESCRIPTION OF EMBODIMENTS

Exemplary embodiments of a wet-etching jig according to the present invention will be explained below in detail with reference to the accompanying drawings. The present invention is not limited to the embodiments.

### First Embodiment

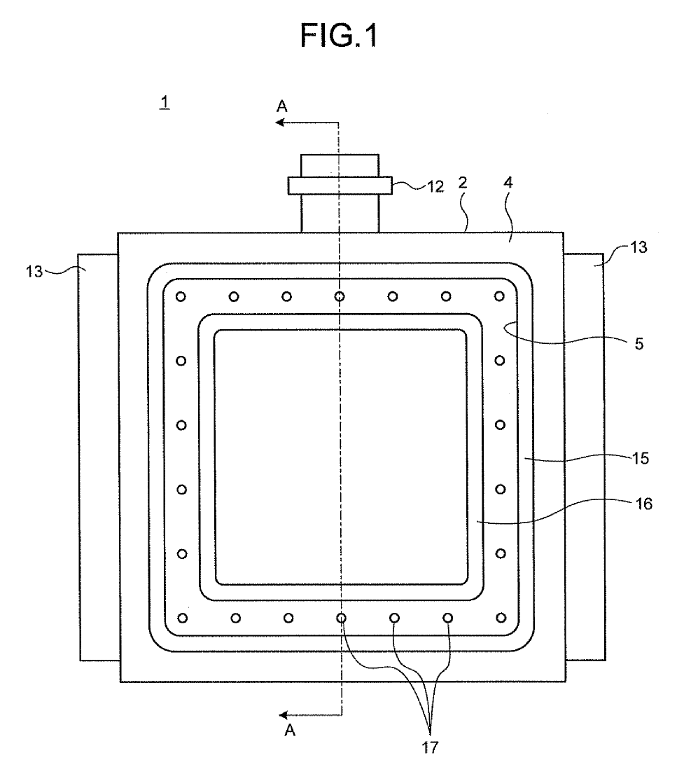

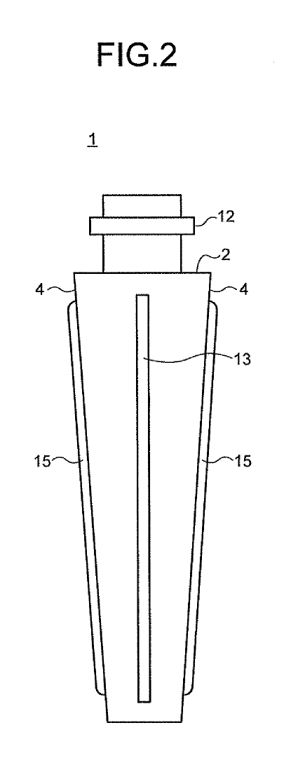

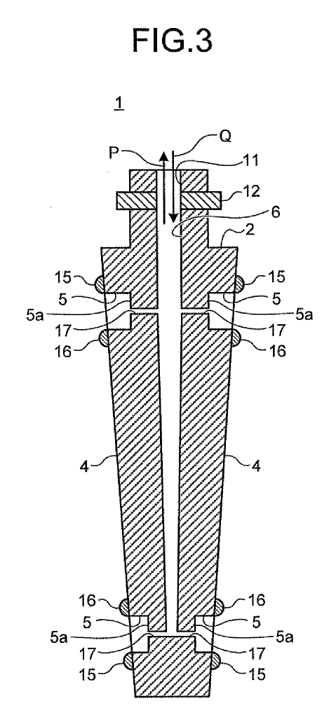

FIG. 1 is a front view of an external appearance of a wet-etching jig according to a first embodiment of the present invention. FIG. 2 is a side view of the wet-etching jig shown in FIG. 1. FIG. 3 is a cross-sectional view taken along a line A-A in a direction of arrows shown in FIG. 1. A wet-etching jig 1 includes a main body 2, a check valve 12, and O-rings 15 and 16.

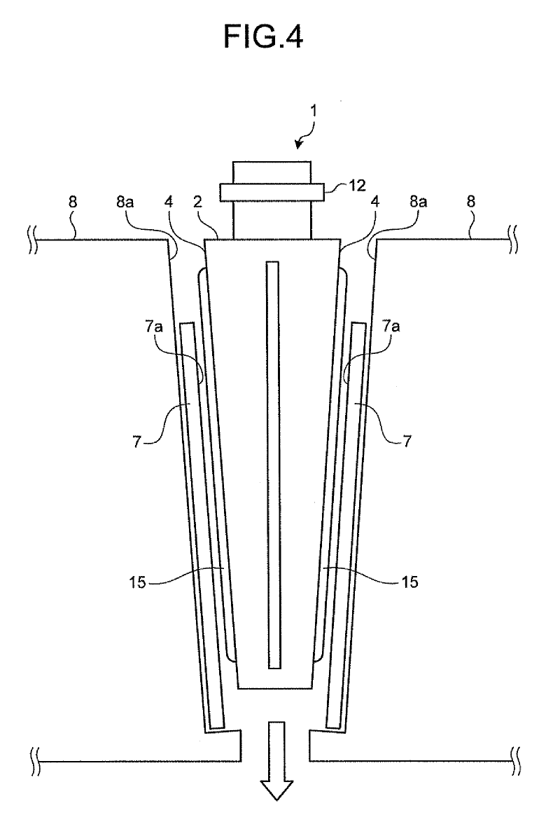

The main body 2 is a substantially rectangular parallelepiped. Among a plurality of surfaces that constitute the main body 2, two surfaces in opposite directions function as holding surfaces 4 that hold workpieces, respectively. The first O-ring (first close contact unit) 15 that is annular to surround substantially entirety of each of the holding surfaces 4 is attached to each of the holing surfaces 4. A shape and an area of a region of the holding surface 4 surrounded by the first O-ring 15 are substantially equal to those of one surface (a first surface 7a of a wafer 7 to be described later, also see FIG. 4) of one workpiece. The first O-ring 15 can be thereby brought into close contact with the one surface to surround substantially entirety (a predetermined region) of the surface of the workpiece.

Furthermore, the second O-ring (second close contact unit) 16 that is annular to be located on the inner side of the first O-ring 15 is attached to each of the holding surfaces 4. For example, the O-rings 15 and 16 are made of an elastic material such as rubber.

In each holding surface 4, a groove 5 is formed between the first O-ring 15 and the second O-ring 16. Suction ports 17 for absorbing air are formed side by side on a bottom 5a of the groove 5. While the groove 5 functions as a suction unit in which the suction ports 17 are formed, the suction unit is not necessarily a groove but the holding surface 4 can be entirely flat. Also in this case, a region between the first O-ring 15 and the second O-ring 16 functions as the suction unit in which the suction ports 17 are formed. Furthermore, only one suction port 17 can be formed instead of forming a plurality of suction ports 17.

An exhaust path 6 that communicates with the suction ports 17 is formed within the main body 2. A connection port 11 to which a tube (not shown) extending from a vacuum pump (not shown) is connected is formed in the main body 2. The exhaust path 6 has one end communicating with the suction ports 17 and the other end communicating with the connection port 11.

The wet-etching jig 1 is normally used in a state in which the connection port 11 is located on an upper side. “Upper” and “lower” mean upper and lower in the state in which the wet-etching jig 1 is normally used, hereinafter. The main body 2 is formed in such a manner that a distance between the holding surfaces 4 becomes smaller at a lower position. As shown in FIG. 2, therefore, the main body 2 has a shape that becomes narrower at a lower position in the side view of the main body 2.

Overhang units 13 are formed on side surfaces of the main body 2 other than the holding surfaces 4, respectively. The overhang units 13 function as positioning units for positioning the wet-etching jig 1 in a cassette to be described later.

The check valve 12 is provided halfway along the exhaust path 6. The check valve 12 permits a flow of the air (a flow indicated by an arrow P) in a direction from the suction ports 17 to the connection port 11, and intercepts a flow of the air (a flow indicated by an arrow Q) in a direction from the connection port 11 to the suction ports 17.

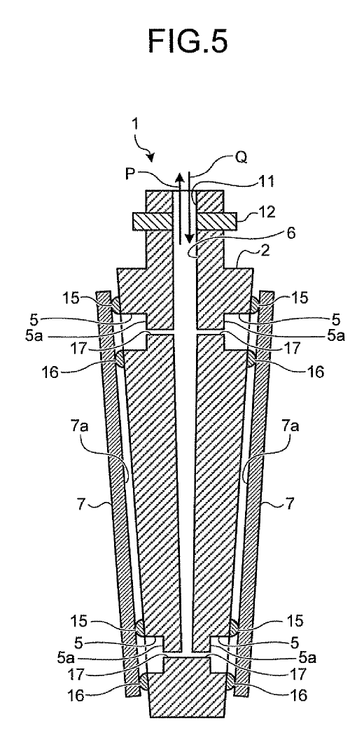

FIG. 4 depicts a state where the wet-etching jig 1 holds wafers. FIG. 5 is a cross-sectional view of the wet-etching jig 1 that holds the wafers. FIG. 6 is a front view of the wet-etching jig 1 that holds the wafers.

As shown in FIG. 4, the wet-etching jig 1 holds the wafers 7 that serve as workpieces by using a wafer setting jig 8 in which a mount groove 8a for mounting the wafers 7 is formed. The mount groove 8a of the wafer setting jig 8 is formed along gradients of the holding surfaces 4 and becomes narrower at a position closer to a bottom thereof. By resting the wafers 7 against both walls of the mount groove 8a and inserting the wet-etching jig 1 into the mount groove 8a, the O-rings 15 and 16 can be brought into close contact with the first surfaces 7a of the wafers 7. Because FIG. 4 depicts a state before the wet-etching jig 1 is completely inserted into the mount groove 8a, the O-rings 15 and 16 do not closely contact the wafers 7 yet. By further inserting the wet-etching jig 1 from the state shown in FIG. 4, the O-rings 15 and 16 can be brought into close contact with the wafers 7.

In a state where the wafers 7 closely contact the O-rings 15 and 16, the vacuum pump connected to the connection port 11 absorbs the air from the suction ports 17. By depressurizing a space between the groove 5 formed in each holding surface 4 and each wafer 7, the wafer 7 is absorbed onto the holding surface 4 and held by the wet-etching jig 1. In this way, the groove 5 in which the suction ports 17 are formed and the O-rings 15 and 16 configure a holding unit that holds the wafers 7.

In this case, because the check valve 12 is provided halfway along the exhaust path 6, the air does not flow into the wet-etching jig 1 from the connection port after depressurizing the space between the groove 5 and each wafer 7. Even after the vacuum pump and the connection port 11 are disconnected, the wet-etching jig 1 can keep the state of holding the wafers 7. Therefore, it is unnecessary to prepare vacuum pumps and tubes in proportion to the number of wet-etching jigs 1, and it is possible to meet the demand of processing a great number of wafers 7 and to contribute to suppressing the manufacturing cost of solar cells. Furthermore, because it suffices to use one wet-etching jig 1 to hold a plurality of wafers 7, processing of a great number of wafers 7 can be more easily handled.

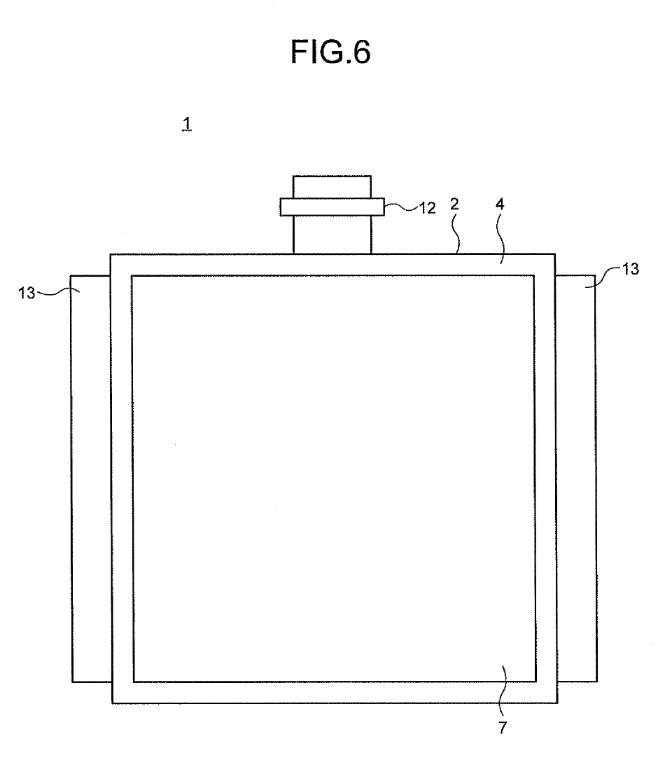

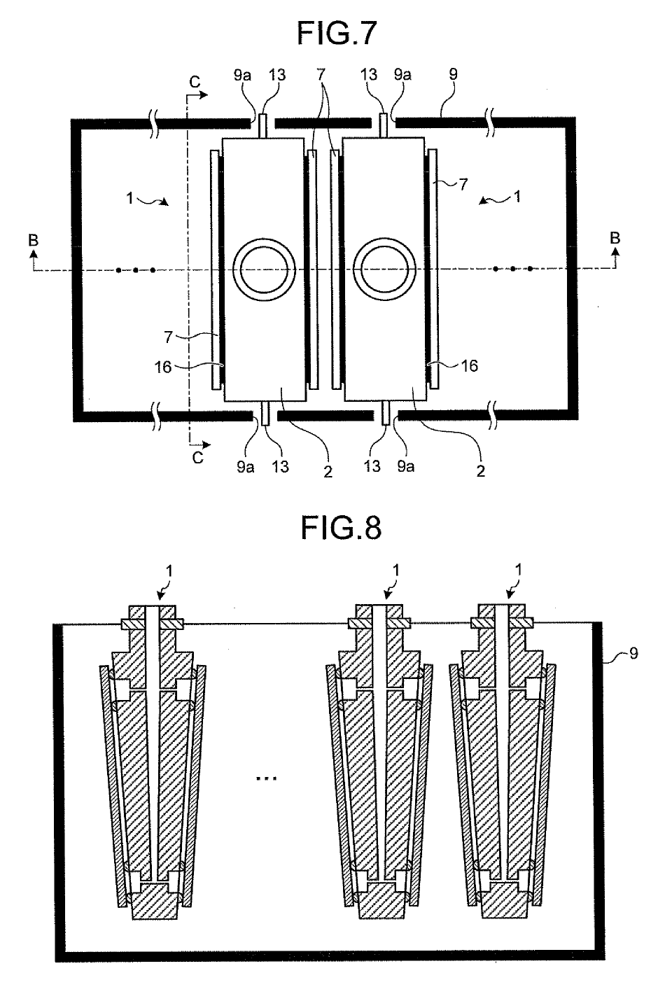

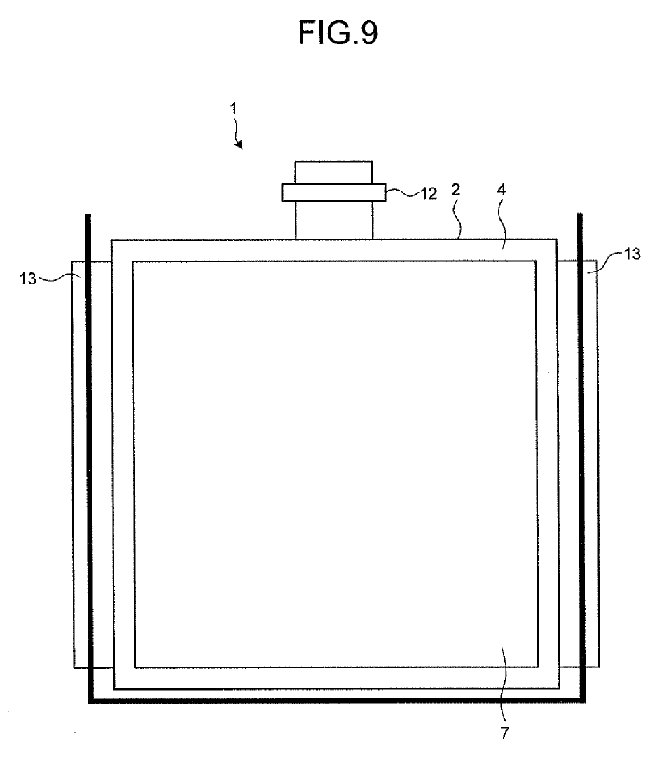

The wet-etching jig 1 in the state of holding the wafers 7 is housed in a cassette. FIG. 7 is a plan view of a state of housing wet-etching jigs in a cassette. FIG. 8 is a cross-sectional view taken along a line B-B in a direction of arrows shown in FIG. 7. FIG. 9 is a view taken along a line C-C in a direction of arrows shown in FIG. 7.

The wet-etching jigs 1 are housed side by side in a cassette 9 so that the held wafers 7 face each other. At this time, the overhang units 13 of each wet-etching jig 1 are fitted into a holding groove 9a formed in the cassette 9, thereby positioning the wet-etching jig 1 in the cassette 9. Furthermore, because of fitting of the overhang units 13 into the holding groove 9a, each wet-etching jig 1 is restricted from moving in the cassette 9, which prevents adjacent wafers from colliding against each other and from being damaged.

The cassette 9 in which the wet-etching jigs 1 are housed is dipped in a chemical solution, whereby the wafers 7 can be etched. In this case, because almost the entire region of the first surface 7a of the wafer 7 is surrounded by the first O-ring 15, the first surface 7a of each wafer 7 does not contact the chemical solution and is not etched. Therefore, it is possible to form “Tex.” only on an opposite surface to the first surface 7a by etching. The shape or size of the predetermined region surrounded by the first O-ring 15 on the first surface 7a of the wafer 7 can be changed by changing a shape or size of the first O-ring 15. That is, by changing the shape or size magnitude of the first O-ring 15, the region etched by the chemical solution on the first surface 7a of the wafer 7 can be set to have a desired shape or size.

Furthermore, the second O-ring 16 is provided on the inner side of the first O-ring 15 and the suction ports 17 are formed between these O-rings 15 and 16. Accordingly, it is only an outer circumferential portion of the first surface 7a of each wafer 7 that is practically absorbed onto the holding surface 4. Therefore, as compared with a case of sucking the entire wafer 7 without providing the second O-ring 16, it is possible to suppress warpage of the wafer 7, to prevent damage of the wafer 7, and to realize a uniform etching process.

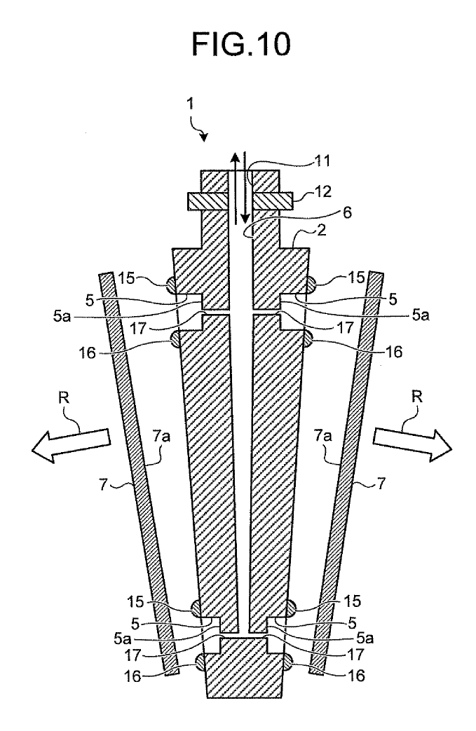

FIG. 10 depicts a state of detaching the wafers 7 from the wet-etching jig 1. When the etching of the wafers 7 is finished, the wet-etching jigs 1 are taken out from the cassette 9 and the wafers 7 are detached from the wet-etching jigs 1. For example, a communication port that communicates with the exhaust path 6 is formed separately from the connection port 11 in the main body 2, and a valve provided on the communication port is opened, thereby flowing the air into the exhaust path 6 and releasing depressurization of the space between each wafer 7 and the groove 5.

As described above, the holding surfaces 4 are formed in such a manner that the distance between the holding surfaces 4 becomes smaller at a lower position, which means that the wafers 7 are held in such a manner that a distance between the wafers 7 becomes smaller at a lower position, accordingly (also see FIG. 5). Therefore, the wafers 7 fall in a direction indicated by arrows R when the wafers 7 are detached from the wet-etching jig 1, and the direction in which the wafers 7 fall is determined substantially uniquely. Because the direction in which the wafers 7 fall is determined uniquely, it is difficult for the detached wafers 7 to contact each other, which facilitates, for example, smoothly performing an operation for picking up the detached wafers 7. Furthermore, because a behavior of each detached wafer 7 can be easily known, it is possible to easily know a distance between the wet-etching jigs 1 that enables to prevent the collision of the detached wafers 7.

The holding unit can be configured without providing the second O-ring 16. When warpage of the wafers 7 is less, for example, when an area of each wafer 7 is smaller, a problem of deformation of the wafers 7 occurs less likely to occur even when the entire wafers are absorbed without providing the second O-ring 16.

### INDUSTRIAL APPLICABILITY

As described above, the wet-etching jig according to the present invention is useful in wet-etching of wafers and particularly suitable for wet-etching of only one surface of each wafer.

### REFERENCE SIGNS LIST

1 WET-ETCHING JIG

2 MAIN BODY

4 HOLDING SURFACE

5 GROOVE

5a BOTTOM

6 EXHAUST PATH

7 WAFER

7a FIRST SURFACE

8 WAFER SETTING JIG

8a MOUNT GROOVE

9 CASSETTE

9a HOLDING GROOVE

11 CONNECTION PORT

12 CHECK VALVE

13 OVERHANG UNIT

15 FIRST O-RING (FIRST CLOSE CONTACT UNIT)

16 SECOND O-RING (SECOND CLOSE CONTACT UNIT)

17 SUCTION PORT

P, Q, R ARROW

1. A wet-etching jig that holds a plate workpiece when the workpiece is wet-etched, the wet-etching jig comprising:
at least two holding units, each including a suction unit in which a suction port is formed for absorbing air, and a first close contact unit that is provided to surround the suction unit and that can closely contact a first surface of the workpiece to surround a predetermined region of the first surface;
an exhaust path that communicates with the suction port;
a check valve that is provided in the exhaust path to intercept a flow of the air in a direction toward the suction unit and to permit a flow of the air from the suction unit, and
at least two of the holding units are located to face in opposite directions.

2. The wet-etching jig according to claim 1, wherein
the two holding units are formed in such a manner that a distance between two workpieces held by the holding units becomes smaller at a vertically lower position when the workpieces are wet-etched.

3. The wet-etching jig according to claim 1, wherein
each holding unit further includes a second close contact unit that is provided annularly on an inner side of the first close contact unit, and
the suction port is provided between the first close contact unit and the second close contact unit.

4. The wet-etching jig according to claim 2, wherein the exhaust path is provided at a vertically upper position.

5. The wet-etching jig according to claim 3, wherein the exhaust path is provided at a vertically upper position.
